(19) United States
(12) Patent Application Publication
(10) Pub. No.: US 2026/0160805 A1
(43) Pub. Date: Jun. 11, 2026

(54) BURN-IN DEVICE FOR LAYERED TEMPERATURE CONTROL

(71) Applicant: King Yuan ELECTRONICS CO., LTD., Hsinchu City (TW)

(72) Inventors: Ta-Kang Liu, Hsinchu City (TW); Ming-Hsien Lee, Hsinchu City (TW); Tsung-Yi Lin, Hsinchu City (TW)

(73) Assignee: King Yuan ELECTRONICS CO., LTD., Hsinchu City (TW)

(21) Appl. No.: 19/307,211

(22) Filed: Aug. 22, 2025

(30) Foreign Application Priority Data
Dec. 6, 2024 (TW) 113147533

(51) Int. Cl. G01R 31/28

(52) U.S. Cl. CPC G01R 31/2875

(57) ABSTRACT

A burn-in device for layered temperature control is provided. The burn-in device for layered temperature control includes a fastening bracket, a hollow plate and a fluid supply device. The hollow plate is arranged at the fastening bracket and has a first fluid chamber. The hollow plate is adapted to carry a burn-in board. The fluid supply device is adapted to provide a temperature controlled fluid to the first fluid chamber of the hollow plate.

### CROSS-REFERENCE TO RELATED APPLICATION

This non-provisional application claims priority under 35 U.S.C. § 119(a) to Patent Application No. 113147533 filed in Taiwan, R.O.C. on Dec. 6, 2024, the entire contents of which are hereby incorporated by reference.

### BACKGROUND

### Technical Field

The disclosure relates to a burn-in technology, and in particular to a burn-in device for layered temperature control.

### Related Art

Nowadays, after electronic elements are manufactured, it is often necessary to carry out reliability testing, such as burn-in testing, to eliminate defective products and ensure product quality. The burn-in testing is generally completed by a burn-in machine. In order to carry out high-wattage burn-in testing, it is necessary to control a burn-in temperature in a particular temperature range, so the burn-in machine also has a heat dissipation function to assist in temperature control. At present, the heat dissipation of the burn-in machine is generally only for the electronic element carried by the socket. However, this cannot achieve uniform heat dissipation of the burn-in board, so that the burn-in board and the circuit thereof are easily damaged and thus it is impossible to carry out function testing of the electronic element.

### SUMMARY

In view of the above, the disclosure provides a burn-in device for layered temperature control. In some embodiments, the burn-in device for layered temperature control includes a fastening bracket, a hollow plate, and a fluid supply device. The hollow plate is arranged at the fastening bracket and has a first fluid chamber. The hollow plate is adapted to carry a burn-in board. The fluid supply device is adapted to provide a temperature controlled fluid to the first fluid chamber of the hollow plate.

In some embodiments, the burn-in device for layered temperature control includes a fastening bracket, a negative pressure plate, an exhaust channel, and an exhaust device. The negative pressure plate is arranged at the fastening bracket and adapted to carry a burn-in board. The negative pressure plate includes a negative pressure channel, and a top surface and a bottom surface that are opposite. The top surface faces the burn-in board. The bottom surface is provided with at least one first air intake vent. The top surface is provided with at least one second air intake vent. The at least one first air intake vent and the at least one second air intake vent are in communication with the negative pressure channel. The exhaust channel is in communication with the negative pressure channel. The exhaust device is adapted to extract a gas from the exhaust channel.

Based on the above, according to some embodiments, the disclosure can uniformly control the temperature of the burn-in board, thereby improve the temperature uniformity of the burn-in board (for example, uniformly remove accumulated heat of the burn-in board), thereby prolonging the service life of the test circuit of the burn-in board used for testing functions of the burn-in element, i.e., reducing the risk of damage to the burn-in board and the test circuit.

### BRIEF DESCRIPTION OF THE DRAWINGS

FIG. 1 is a schematic three-dimensional view of a burn-in device for layered temperature control according to a first embodiment of the disclosure;

FIG. 2 is a schematic partial side view of the burn-in device for layered temperature control according to the first embodiment of the disclosure;

FIG. 3 is a schematic partial side view of a burn-in device for layered temperature control according to a second embodiment of the disclosure;

FIG. 4 is a schematic partial side view of a burn-in device for layered temperature control according to a third embodiment of the disclosure;

FIG. 5 is a schematic partial side view of a burn-in device for layered temperature control according to a fourth embodiment of the disclosure;

FIG. 6 is a schematic partial block diagram of a burn-in device for layered temperature control according to some embodiments of the disclosure;

FIG. 7 is a schematic partial view of a burn-in device for layered temperature control according to some embodiments of the disclosure;

FIG. 8 is a schematic partial side view of a burn-in device for layered temperature control according to some embodiments of the disclosure;

FIG. 9 is a schematic partial side view of a burn-in device for layered temperature control according to a fifth embodiment of the disclosure;

FIG. 10 is a schematic partial side view of a burn-in device for layered temperature control according to a sixth embodiment of the disclosure; and

FIG. 11 is a schematic partial side view of a burn-in device for layered temperature control according to a seventh embodiment of the disclosure.

### DETAILED DESCRIPTION

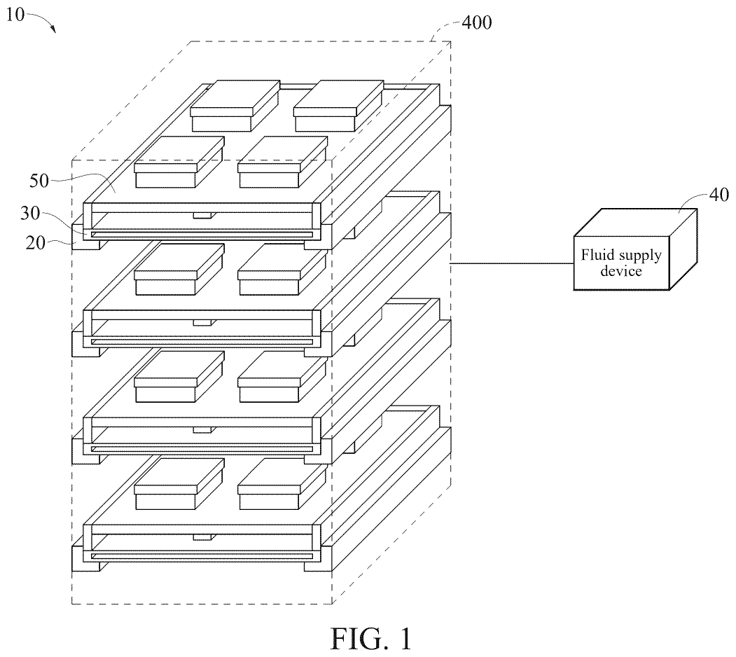

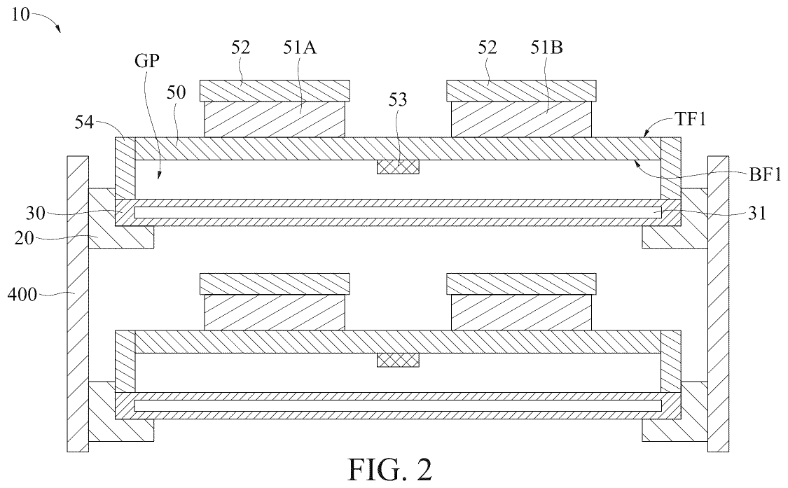

Referring to FIG. 1 and FIG. 2, FIG. 1 is a schematic three-dimensional view of a burn-in device 10 for layered temperature control according to a first embodiment of the disclosure, and FIG. 2 is a schematic partial side view of the burn-in device 10 for layered temperature control according to the first embodiment of the disclosure. The burn-in device 10 for layered temperature control includes a fastening bracket 20, a hollow plate 30, and a fluid supply device 40. Here, FIG. 1 shows four fastening brackets 20 and four hollow plates 30, and FIG. 2 shows two fastening brackets 20 and two hollow plates 30, but the disclosure is not limited thereto. An amount of the fastening brackets 20 corresponds to an amount of the hollow plates 30, and may be one or more. In some embodiments, the fastening brackets 20 and the hollow plates 30 are arranged in one dimension, for embodiment, arranged vertically. The description will be made with a single fastening bracket 20, a single hollow plate 30, and related structures thereof later.

The hollow plate 30 is arranged at the fastening bracket 20 so as to be supported by the fastening bracket 20. For example, two sides of the hollow plate 30 are connected to the fastening bracket 20. The hollow plate 30 is adapted to carry a burn-in board 50. For example, two sides of the hollow plate 30 are provided with slide grooves, allowing two sides of the burn-in board 50 to slide in so as to be fixed to the hollow plate 30. A top surface (referred to as a first top surface TF1) of the burn-in board 50 has at least one burn-in seat (for example, a first burn-in seat 51A and a second burn-in seat 51B) for the arrangement of a burn-in element 52. A bottom surface (referred to as a first bottom surface BF1) of the burn-in board 50 is provided with a test circuit 53 to test functions of the burn-in element 52 during burn-in testing. In some embodiments, the burn-in element 52 is a semiconductor package, and the burn-in seat is a chip socket.

The hollow plate 30 has a first fluid chamber 31. The fluid supply device 40 is adapted to provide a temperature controlled fluid to the first fluid chamber 31 of the hollow plate 30. In this way, the first fluid chamber 31 in which the temperature controlled fluid flows can uniformly take away the heat of the burn-in board 50 or provide heat to the burn-in board 50 so as to control a temperature of the burn-in board 50 and improve the temperature uniformity of the burn-in board 50, thereby reducing the risk of damage to the burn-in board 50. For example, when the temperature controlled fluid is a high-temperature fluid, the temperature of the burn-in board 50 can be uniformly increased. When the temperature controlled fluid is a low-temperature fluid, accumulated heat of the burn-in board 50 can be uniformly removed. In other words, by providing the high-temperature or low-temperature temperature controlled fluid, the hollow plate 30 can be maintained at high temperature or low temperature, thereby creating a high-temperature or low-temperature test environment.

Furthermore, since the test circuit 53 of the burn-in board 50 is disposed at the first bottom surface BF1 of the burn-in board 50, the hollow plate 30 is closer to the test circuit 53, so that the temperature of the test circuit 53 can be effectively controlled. For example, when the low-temperature temperature controlled fluid is provided to the hollow plate 30, the test circuit 53 can be continuously cooled or the test circuit 53 can be maintained at a specific temperature to reduce the risk of damage to the test circuit 53, thereby prolonging the service life of the test circuit 53.

In some embodiments, the fluid supply device 40 may be a cooling distribution unit (CDU) or a chiller to directly provide a low-temperature liquid. In other embodiments, the fluid supply device 40 may be a cooling gas supply device to directly provide a low-temperature gas (such as liquid nitrogen) or temperature-regulated air, and a temperature of the air may be regulated, for example, by a condenser or a heat exchanger. In another embodiment, the fluid supply device 40 may also provide a high-temperature gas or a high-temperature liquid, for example, a liquid or a gas temperature-regulated by a heater. The heater may be a heater formed by an electric heating element, a resistive heating source, or other equivalent elements that can be controlled to heat up.

As shown in FIG. 2, in some embodiments, the burn-in board 50 has a vertical bracket 54 disposed around a body of the burn-in board 50, so that the burn-in board 50 and the hollow plate 30 are spaced apart by a gap GP. In this way, the hollow plate 30 can take away the heat of the air in the space formed by the gap GP through air convection, so as to indirectly reduce the temperature of the burn-in board 50. In other embodiments, for example, the hollow plate 30, when functioning to heat up, provides heat to the air in the space formed by the gap GP through air convection, so as to indirectly increase the temperature of the burn-in board 50. This can avoid direct heat conduction, by heat conduction, between the hollow plate 30 and the burn-in board 50 causes damage to the burn-in board 50 due to drastic instantaneous changes in temperature.

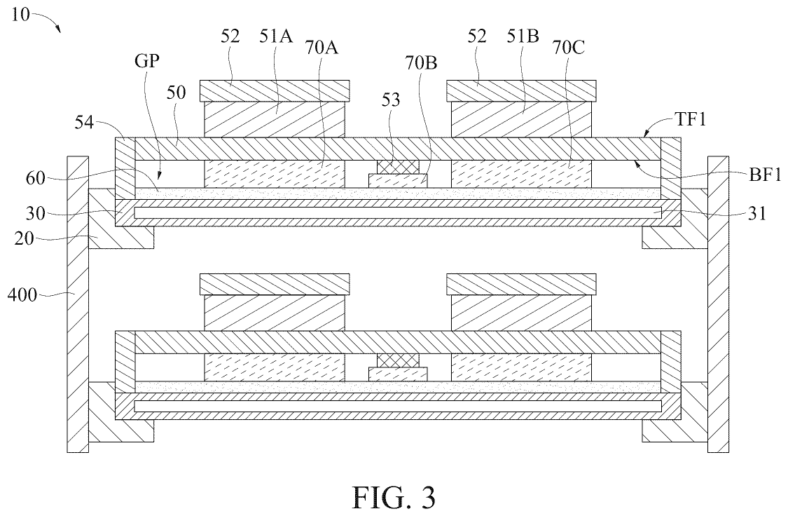

FIG. 3 is a schematic partial side view of a burn-in device 10 for layered temperature control according to a second embodiment of the disclosure. The second embodiment is different from the first embodiment in that the burn-in device 10 for layered temperature control further includes a bottom board 60 and at least one heat conducting block (for example, a first heat conducting block 70A, a second heat conducting block 70B, and a third heat conducting block 70C). The heat conducting block is disposed between the burn-in board 50 and the bottom board 60, and the bottom board 60 is in direct contact with the hollow plate 30. In this way, the hollow plate 30 can effectively transfer heat to the burn-in board 50 through the bottom board 60 and the heat conducting block by heat conduction, thereby effectively controlling the temperature of the burn-in board 50. Besides, when the burn-in board 50 is taken out of the burn-in device 10 for layered temperature control or the burn-in board 50 is put into the burn-in device 10 for layered temperature control, the bottom board 60 can be moved (for example, taken out or put in) together with the burn-in board 50. Therefore, through the isolation of the bottom board 60, when a user may contact the bottom board 60 only when taking the burn-in board 50 out of the burn-in device 10 for layered temperature control or putting the burn-in board into the burn-in device for layered temperature control, thereby preventing the user from directly touching the burn-in board 50 and further reducing the risk of damage to the burn-in board 50 due to the user's touch.

In some embodiments, two ends of part of the heat conducting blocks (for example, the first heat conducting block 70A and the third heat conducting block 70C) are respectively in contact with a corresponding area of the first bottom surface BF1 of the burn-in board 50 where the burn-in seat (for example, the first burn-in seat 51A and the second burn-in seat 51B) is vertically projected and the bottom board 60. Therefore, the hollow plate 30 can control the temperature of the burn-in seat by direct heat conduction in a path having the minimum thermal resistance. Two ends of the other part of the heat conducting blocks (for example, the second heat conducting block 70B) are respectively in contact with the test circuit 53 and the bottom board 60. In some embodiments, the test circuit 53 may be an electronic element with high thermal design power (TDP), such as a controller chip or a voltage regulator module (VRM). Thereby, the hollow plate 30 can adjust the temperature of the test circuit 53 through the heat conducting block by direct heat conduction.

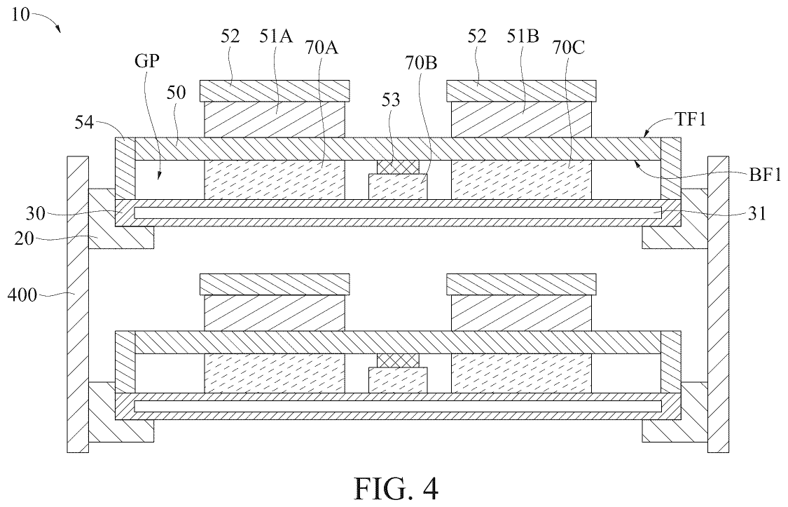

FIG. 4 is a schematic partial side view of a burn-in device 10 for layered temperature control according to a third embodiment of the disclosure. The burn-in device 10 for layered temperature control in the third embodiment also includes a fastening bracket 20, a hollow plate 30, a fluid supply device 40, and at least one heat conducting block (for example, a first heat conducting block 70A, a second heat conducting block 70B, and a third heat conducting block 70C). The difference is that the heat conducting block is disposed at a first bottom surface BF1 of the burn-in board 50 and in direct contact with the hollow plate 30. For example, two ends of part of the heat conducting blocks (for example, the first heat conducting block 70A and the third heat conducting block 70C) are respectively in contact with a corresponding area of the first bottom surface BF1 of the burn-in board 50 where the burn-in seat (for example, the first burn-in seat 51A and the second burn-in seat 51B) is vertically projected and the hollow plate 30, and two ends of the other part of the heat conducting blocks (for example, the second heat conducting block 70B) are respectively in contact with the test circuit 53 and the hollow plate 30. Thereby, the heat control is achieved by simply using the heat conducting blocks as the media for heat conduction between the burn-in board 50 and the hollow plate 30, i.e., by minimum thermal resistance, which can further improve the temperature control of the test circuit 53 and the burn-in element 52 on the burn-in seat.

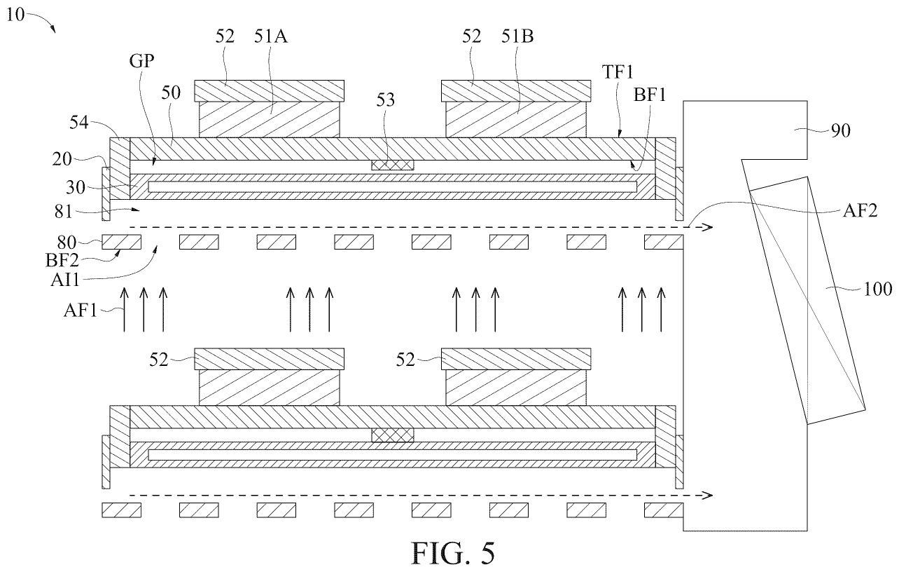

FIG. 5 is a schematic partial side view of the burn-in device 10 for layered temperature control according to a fourth embodiment of the disclosure. The fourth embodiment is different from the first embodiment in that the burn-in device 10 for layered temperature control further includes a negative pressure plate 80, an exhaust channel 90, and an exhaust device 100. The negative pressure plate 80 is arranged below the hollow plate 30 and includes a bottom surface (referred to as a second bottom surface BF2) and a negative pressure channel 81. The second bottom surface BF2 is provided with at least one air intake vent (referred to as a first air intake vent AI1) in communication with the negative pressure channel 81.

Thereby, hot air (as shown by arrow AF1 in FIG. 5) emitted by the lower burn-in elements 52 adjacent to the second bottom surface BF2 is sucked into the negative pressure channel 81 via the first air intake vent AI1 above the burn-in elements 52. The negative pressure channel 81 is in communication with the exhaust channel 90 such that the gas sucked in is transferred to the exhaust channel 90 (as shown by arrow AF2 in FIG. 5). The exhaust channel 90 can converge hot air discharged by the negative pressure channels 81 of all layers.

In addition, in the exhaust channel 90 or in a space where the exhaust channel 90 is in communication with the outside atmosphere, the exhaust device 100 may be arranged. The exhaust device is adapted to extract a gas from the exhaust channel 90 and discharge the gas to the atmosphere. Thereby, the exhaust device 100 can discharge hot air emitted by the burn-in elements 52 by means of air convection, which will not produce the heat accumulation effect or thermal crosstalk effect. Besides, in some embodiments, the negative pressure channel 81 may be formed of the negative pressure plate 80 and the hollow plate 30. When a low-temperature temperature controlled fluid flows in the hollow plate 30, the hot air in the negative pressure channel 81 can be further cooled, thereby reducing the temperature of the gas discharged to the atmosphere.

The exhaust device 100 is, for example, but not limited to, an exhaust fan. Moreover, in some embodiments, the exhaust device 100 may discharge air obliquely upward, so as to avoid affecting other devices. The second embodiment of FIG. 3, the third embodiment of FIG. 4 and the fourth embodiment of FIG. 5 may be applied mutually. For a corresponding relationship derived from the mutual applications, reference may be made to FIG. 3 to FIG. 5, and details will not be repeated here.

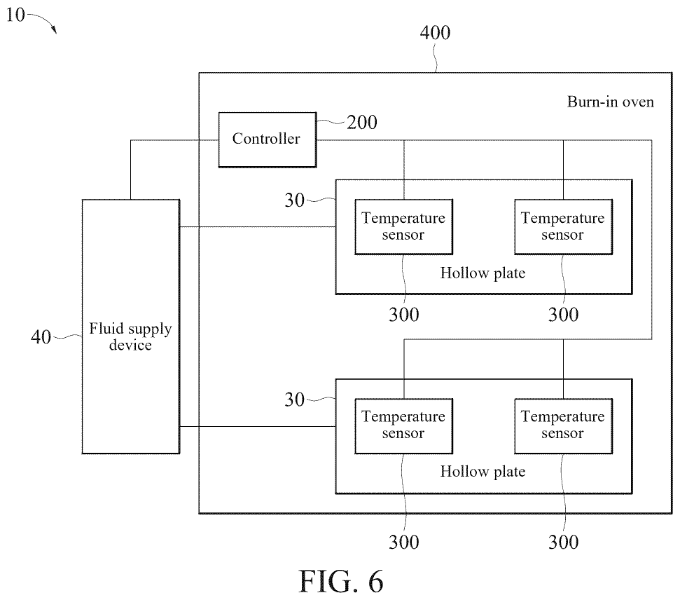

FIG. 6 is a schematic partial block diagram of a burn-in device 10 for layered temperature control according to some embodiments of the disclosure. In some embodiments, the burn-in device 10 for layered temperature control further includes a controller 200 and at least one temperature sensor 300. The controller 200 is electrically connected to the temperature sensor 300 and the fluid supply device 40. The temperature sensor 300 may be arranged at the hollow plate 30 and detect a temperature of the burn-in element 52 of the burn-in board 50 carried by the hollow plate 30. An amount of the temperature sensors 300 may correspond to an amount of the burn-in elements 52, and the temperature sensors 300 are respectively distributed in corresponding areas of the hollow plate 30 where the burn-in seats are vertically projected to detect the temperatures of the burn-in elements 52 carried by the burn-in seats in one-to-one correspondence. In other embodiments, the temperature sensor 300 may also be arranged at any position in a burn-in oven 400 (shown in FIG. 1 and detailed later) or in the exhaust channel 90 (shown in FIG. 5).

In addition, the controller 200 may control a flow rate or temperature of the temperature controlled fluid provided by the fluid supply device 40 according to the detected temperature of the burn-in element 52 of the burn-in board 50. For example, if the temperature sensor 300 detects that the temperature of the burn-in element 52 is greater than a first temperature threshold, it sends a cooling signal to the controller 200, and the controller 200 controls, in response to the cooling signal, the fluid supply device 40 to reduce the temperature of the provided temperature controlled fluid or increase the flow rate of the temperature controlled fluid. On the other hand, if the temperature sensor 300 detects that the temperature of the burn-in element 52 is less than a second temperature threshold, it sends a heating signal to the controller 200, and the controller 200 controls, in response to the heating signal, the fluid supply device 40 to increase the temperature of the provided temperature controlled fluid or reduce the flow rate of the temperature controlled fluid. The first temperature threshold is greater than the second temperature threshold.

In this way, the controller 200 can control the temperatures of the burn-in board 50 and the burn-in element 52 within a particular temperature range (for example, a temperature range formed by the first temperature threshold and the second temperature threshold) through the fluid supply device 40. The controller 200 is, for example, but not limited to, a central processing unit, a microprocessor, an application-specific integrated circuit (ASIC), a system on a chip (SOC), or other arithmetic circuits.

In some embodiments, the controller 200 is further connected to the exhaust device 100, and the controller 200 controls an exhaust volume (i.e., operating speed) of the exhaust device 100 according to the detected temperature of the burn-in element 52 of the burn-in board 50, a temperature in the burn-in oven 400 or a temperature in the exhaust channel 90. For example, if the temperature sensor 300 detects that the temperature of the burn-in element 52 is greater than the first temperature threshold, it sends a cooling signal to the controller 200, and the controller 200 controls the exhaust device 100 to increase its exhaust volume in response to the cooling signal. If the temperature sensor 300 detects that the temperature of the burn-in element 52 is less than the second temperature threshold, it sends a heating signal to the controller 200, and the controller 200 controls the exhaust device 100 to reduce its exhaust volume in response to the heating signal, so that the temperatures of the burn-in board 50 and the burn-in element 52 can be controlled within a particular temperature interval (for example, a temperature range formed by the first temperature threshold and the second temperature threshold).

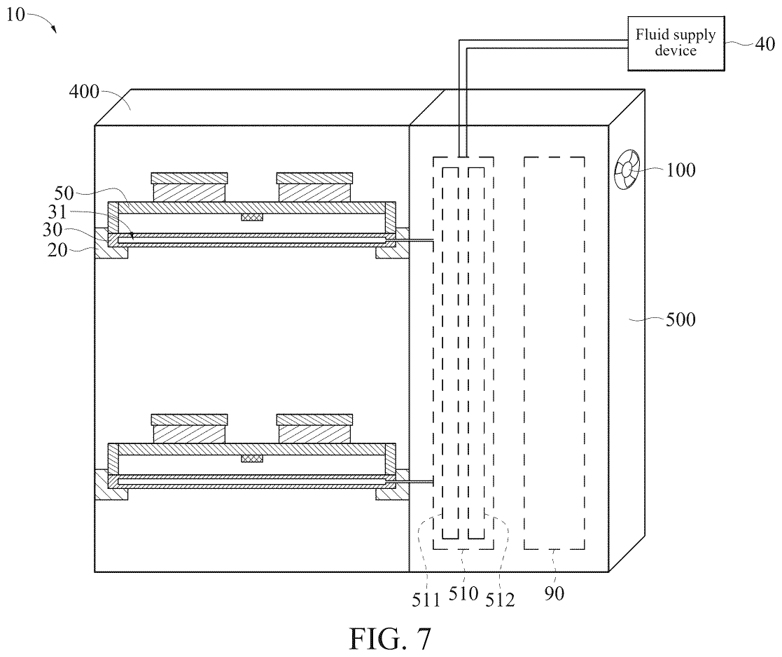

FIG. 7 is a schematic partial view of a burn-in device 10 for layered temperature control according to some embodiments of the disclosure. In some embodiments, the burn-in device 10 for layered temperature control further includes a burn-in oven 400 and a temperature control vertical board 500. The fastening bracket 20, the hollow plate 30, and the burn-in board 50 are accommodated in the burn-in oven 400. The temperature control vertical board 500 is arranged at one side of the burn-in oven 400 and has a second fluid chamber 510. The first fluid chamber 31 is in communication with the second fluid chamber 510, and the second fluid chamber 510 is in communication with the fluid supply device 40. In other words, the first fluid chamber 31, the second fluid chamber 510, and the fluid supply device 40 form a closed fluid circulation loop.

In some embodiments, the second fluid chamber 510 may include a supply loop 511 and a recovery loop 512. The fluid supply device 40 may provide the temperature controlled fluid to the first fluid chamber 31 through the supply loop 511. The fluid supply device 40 may recover the temperature controlled fluid to the first fluid chamber 31 through the recovery loop 512. In this way, the temperature controlled fluid flowing in the first fluid chamber 31 of each of the hollow plates 30 converges to the recovery loop 512 of the second fluid chamber 510 and then flows to the fluid supply device 40 for unified heat exchange treatment such as heating or cooling. The fluid supply device 40 allows the temperature controlled fluid subjected to heat exchange treatment (such as heating or cooling) to flow to the first fluid chamber 31 via the supply loop 511 of the second fluid chamber 510, so as to continue controlling the temperature of the burn-in board 50. Thereby, the temperature regulation effect on the burn-in board 50 can be further improved.

As shown in FIG. 7, in some embodiments, the exhaust channel 90 and the exhaust device 100 are arranged at the temperature control vertical board 500. The exhaust device 100 is adapted to extract a gas in the burn-in oven 400 such that the gas flows through the exhaust channel 90 and is then discharged out of the burn-in oven 400. Specifically, the exhaust device 100 concentrates hot air emitted by each of the burn-in elements 52 of the burn-in boards 50 carried by each of the hollow plates 30 to the exhaust channel 90 by means of air convection and then discharges the concentrated hot air to the atmosphere, without generating the heat accumulation effect or thermal crosstalk effect. In this way, the temperature regulation effect on the burn-in board 50 and the inside of the burn-in oven 400 can be further improved.

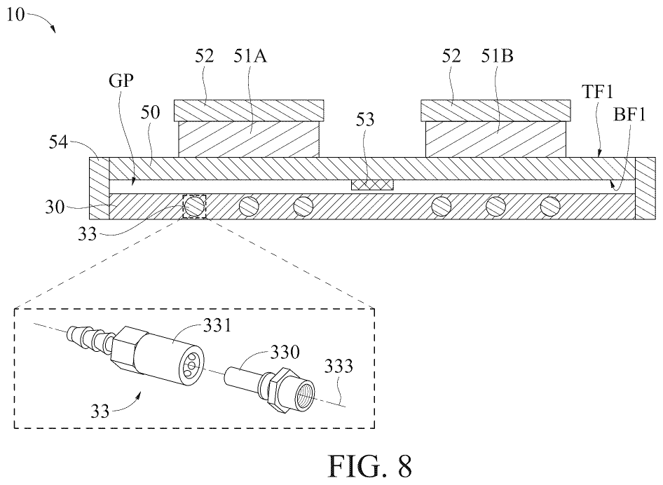

FIG. 8 is a schematic partial side view of a burn-in device 10 for layered temperature control according to some embodiments of the disclosure. In some embodiments, the hollow plate 30 has a fluid connector 33, which may include an insertion pipe 330, a sleeve joint 331, and a flow channel 333 running through the insertion pipe 330 and the sleeve joint 331. The insertion pipe 330 and the sleeve joint 331 may be respectively arranged at the hollow plate 30 and the temperature control vertical board 500, and may be connected by inserting the insertion pipe 330 into the sleeve joint 331 or fitting the sleeve joint 331 into the insertion pipe 330. Therefore, the first fluid chamber 31 (not shown) of the hollow plate 30 may be quickly connected to or separated from the second fluid chamber 510 of the temperature control vertical board 500 through the fluid connector 33.

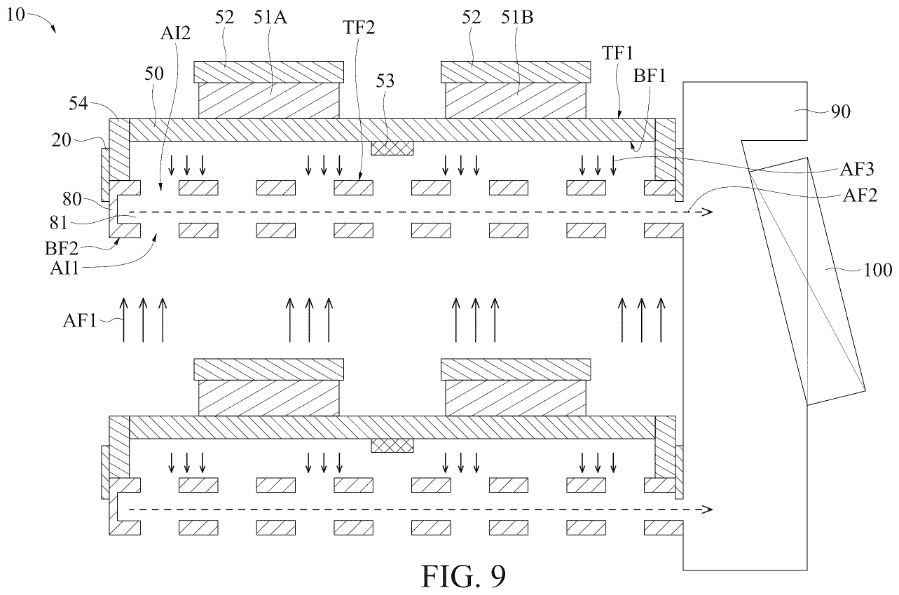

FIG. 9 is a schematic partial side view of a burn-in device 10 for layered temperature control according to a fifth embodiment of the disclosure. In the fifth embodiment, the burn-in device 10 for layered temperature control also includes a fastening bracket 20, a negative pressure plate 80, an exhaust channel 90, and an exhaust device 100. The difference is that in the fifth embodiment, the negative pressure plate 80 is arranged at the fastening bracket 20 and adapted to carry a burn-in board 50. For example, two sides of the negative pressure plate 80 are connected to the fastening bracket 20, and two sides of the negative pressure plate 80 are provided with slide grooves, allowing two sides of the burn-in board 50 to slide in so as to be fixed to the negative pressure plate 80. The negative pressure plate 80 includes a negative pressure channel 81, and a top surface (referred to as a second top surface TF2) and a bottom surface (i.e., a second bottom surface BF2) that are opposite. The second top surface TF2 faces the burn-in board 50. The second bottom surface BF2 is provided with at least one first air intake vent AI1, and the second top surface TF2 is provided with at least one second air intake vent AI2. The first air intake vent AI1 and the second air intake vent AI2 are in communication with the negative pressure channel 81.

Thereby, hot air (as shown by arrow AF3 in FIG. 9) emitted by the first bottom surface BF1 of the burn-in board 50 carried by the negative pressure plate 80 and the test circuit 53 thereof can be sucked into the negative pressure channel 81 via the second air intake vent AI2 by means of air convection, and then the hot air sucked in by the negative pressure channels 81 of all layers is converged (as shown by arrow AF2 in FIG. 9) by the exhaust device 100 through the exhaust channel 90 and discharged to the atmosphere, which can avoid the heat accumulation effect or thermal crosstalk effect of the first bottom surface BF1 of the burn-in board 50 and the test circuit 53 thereof, thereby reducing the risk of damage to the burn-in board 50 and the test circuit 53. Furthermore, hot air (as shown by arrow AF1 in FIG. 9) emitted by the lower burn-in elements 52 adjacent to the second bottom surface BF2 may be sucked into the negative pressure channel 81 via the first air intake vent AI1 by means of air convection, and then the hot air sucked in by the negative pressure channels 81 of all layers is converged by the exhaust device 100 through the exhaust channel 90 and discharged to the atmosphere, which avoids the heat accumulation effect or thermal crosstalk effect of the burn-in board 50. In some embodiments, the first air intake vent AI1 corresponds to the second air intake vent AI2, so that the negative pressure channel 81 has good exhaust capacity. In some embodiments, the first air intake vent AI1 and the second air intake vent AI2 may be distributed corresponding to each other or staggered with each other.

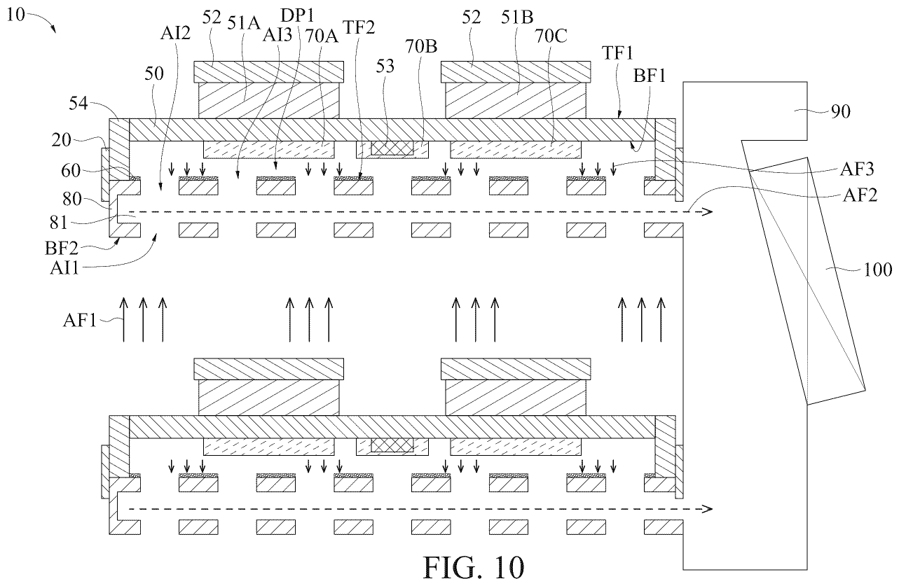

FIG. 10 is a schematic partial side view of a burn-in device 10 for layered temperature control according to a sixth embodiment of the disclosure. The sixth embodiment is different from the fifth embodiment in that the burn-in device 10 for layered temperature control further includes a bottom board 60 and at least one heat conducting block (for example, a first heat conducting block 70A, a second heat conducting block 70B, and a third heat conducting block 70C). The heat conducting block is disposed between the burn-in board 50 and the bottom board 60. The heat conducting block and the bottom board 60 are spaced apart by a distance DP1 such that heat energy of the burn-in board 50 can be dissipated to air in the distance DP1 to form hot air. In other embodiments, the heat conducting block may also be a heat sink to accelerate heat removal of the burn-in board 50.

The bottom board 60 is in contact with the second top surface TF2 of the negative pressure plate 80 and provided with at least one third air intake vent AI3. The third air intake vent AI3 is in communication with the negative pressure channel 81. Thereby, hot air (as shown by arrow AF3 in FIG. 10) formed via the heat conducting block by the first bottom surface BF1 of the burn-in board 50 carried by the negative pressure plate 80 and the test circuit 53 thereof can be sucked into the negative pressure channel 81 via the third air intake vent AI3 and the second air intake vent AI2 by means of air convection, and then the hot air sucked in by the negative pressure channels 81 of all layers is converged (as shown by arrow AF2 in FIG. 10) by the exhaust device 100 through the exhaust channel 90 and discharged to the atmosphere, which can avoid the heat accumulation effect or thermal crosstalk effect of the first bottom surface BF1 of the burn-in board 50 and the test circuit 53 thereof, thereby reducing the risk of damage to the burn-in board 50 and the test circuit 53.

In some embodiments, the first air intake vent AI1, the second air intake vent AI2, and the third air intake vent AI3 correspond to each other (specifically, the first air intake vent AI1, the second air intake vent AI2, and the third air intake vent AI3 are distributed corresponding to each other), so that the negative pressure channel 81 has good exhaust capacity. In other embodiments, the first air intake vent AI1, the second air intake vent AI2, and the third air intake vent AI3 may be staggered with each other. In some embodiments, part of the heat conducting blocks (for example, the first heat conducting block 70A and the third heat conducting block 70C) are in contact with corresponding areas of the first bottom surface BF1 of the burn-in board 50 where the burn-in seats (for example, the first burn-in seat 51A and the second burn-in seat 51B) are vertically projected, and the other part of the heat conducting blocks (for example, the second heat conducting block 70B) is in contact with the test circuit 53. This can further improve the temperature control of the test circuit 53 and the burn-in element 52 on the burn-in seat.

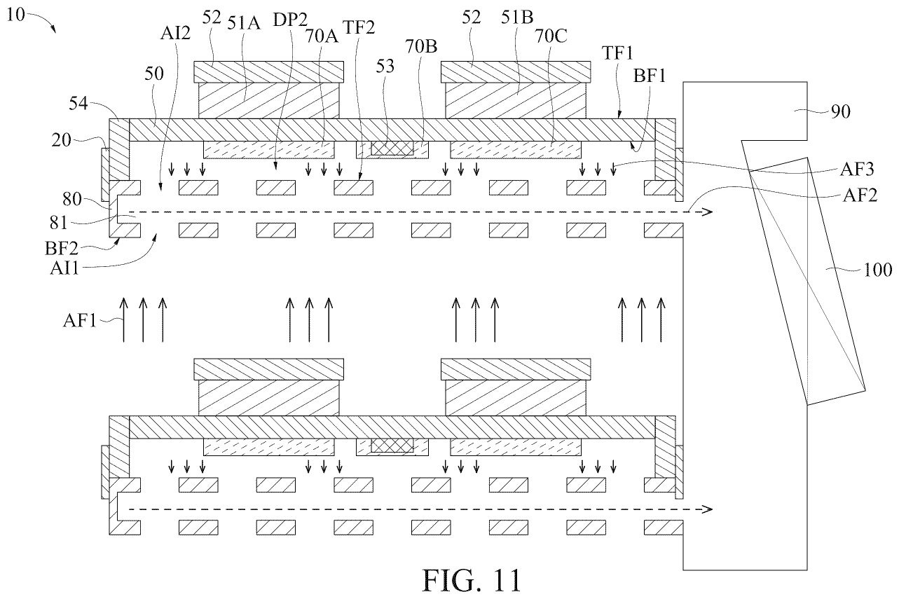

FIG. 11 is a schematic partial side view of a burn-in device 10 for layered temperature control according to a seventh embodiment of the disclosure. The burn-in device 10 for layered temperature control in the seventh embodiment also includes a fastening bracket 20, a negative pressure plate 80, an exhaust channel 90, an exhaust device 100, and at least one heat conducting block (for example, a first heat conducting block 70A, a second heat conducting block 70B, and a third heat conducting block 70C). The difference is that the heat conducting block is disposed between the burn-in board 50 and the negative pressure plate 80. The heat conducting block and the negative pressure plate 80 are spaced apart by a distance DP2 such that heat energy of the burn-in board 50 can be dissipated to air in the distance DP2 to form hot air. In other embodiments, the heat conducting block may also be a heat sink to accelerate heat removal of the burn-in board 50. The hot air is sucked into the negative pressure channel 81 via the second air intake vent AI2 (as shown by arrow AF3 in FIG. 11) by means of air convection, and then the hot air sucked in by the negative pressure channels 81 of all layers is converged (as shown by arrow AF2 in FIG. 11) by the exhaust device 100 through the exhaust channel 90 and discharged to the atmosphere, which can avoid the heat accumulation effect or thermal crosstalk effect.

Based on the above, according to some embodiments, the disclosure can uniformly control the temperature of the burn-in board, thereby improve the temperature uniformity of the burn-in board (for example, uniformly remove accumulated heat of the burn-in board), thereby prolonging the service life of the test circuit of the burn-in board used for testing functions of the burn-in element, i.e., reducing the risk of damage to the burn-in board and the test circuit.

What is claimed is:

1. A burn-in device for layered temperature control, comprising:
a fastening bracket;
a hollow plate, arranged at the fastening bracket and having a first fluid chamber, the hollow plate being adapted to carry a burn-in board; and
a fluid supply device, adapted to provide a temperature controlled fluid to the first fluid chamber of the hollow plate.

2. The burn-in device for layered temperature control according to claim 1, further comprising a bottom board and at least one heat conducting block, wherein the at least one heat conducting block is disposed between the burn-in board and the bottom board, and the bottom board is in contact with the hollow plate.

3. The burn-in device for layered temperature control according to claim 1, further comprising at least one heat conducting block, disposed at a bottom surface of the burn-in board and in contact with the hollow plate.

4. The burn-in device for layered temperature control according to claim 1, further comprising a negative pressure plate, an exhaust channel, and an exhaust device, wherein the negative pressure plate is arranged below the hollow plate and comprises a bottom surface and a negative pressure channel, the bottom surface is provided with at least one air intake vent in communication with the negative pressure channel, the negative pressure channel is in communication with the exhaust channel, and the exhaust device is adapted to extract a gas from the exhaust channel.

5. The burn-in device for layered temperature control according to claim 1, further comprising a controller and at least one temperature sensor, wherein the at least one temperature sensor is arranged at the hollow plate and detects a temperature of at least one burn-in element of the burn-in board carried by the hollow plate, and the controller controls a temperature of the temperature controlled fluid provided to the fluid supply device according to the detected temperature of the at least one burn-in element of the burn-in board.

6. The burn-in device for layered temperature control according to claim 1, further comprising a burn-in oven and a temperature control vertical board, wherein the fastening bracket, the hollow plate, and the burn-in board are accommodated in the burn-in oven, the temperature control vertical board is arranged at one side of the burn-in oven and has a second fluid chamber, and the second fluid chamber is in communication with the first fluid chamber and the fluid supply device.

7. The burn-in device for layered temperature control according to claim 6, further comprising an exhaust channel and an exhaust device that are arranged at the temperature control vertical board, wherein the exhaust device is adapted to extract a gas in the burn-in oven such that the gas flows through the exhaust channel and is then discharged out of the burn-in oven.

8. The burn-in device for layered temperature control according to claim 6, wherein the hollow plate has a fluid connector, and the second fluid chamber is in communication with the first fluid chamber via the fluid connector.

9. A burn-in device for layered temperature control, comprising:
a fastening bracket;
a negative pressure plate, arranged at the fastening bracket and adapted to carry a burn-in board, the negative pressure plate comprising a negative pressure channel, and a top surface and a bottom surface that are opposite, the top surface facing the burn-in board, the bottom surface being provided with at least one first air intake vent, the top surface being provided with at least one second air intake vent, and the at least one first air intake vent and the at least one second air intake vent being in communication with the negative pressure channel;
an exhaust channel, in communication with the negative pressure channel; and
an exhaust device, adapted to extract a gas from the exhaust channel.

10. The burn-in device for layered temperature control according to claim 9, wherein the at least one first air intake vent corresponds to the at least one second air intake vent.

11. The burn-in device for layered temperature control according to claim 9, further comprising a bottom board and at least one heat conducting block, wherein the at least one heat conducting block is disposed between the burn-in board and the bottom board, the bottom board is in contact with the top surface of the negative pressure plate and provided with at least one third air intake vent, and the at least one third air intake vent is in communication with the negative pressure channel.

12. The burn-in device for layered temperature control according to claim 11, wherein the at least one first air intake vent, the at least one second air intake vent, and the at least one third air intake vent correspond to each other.

13. The burn-in device for layered temperature control according to claim 9, further comprising at least one heat conducting block, disposed between the burn-in board and the negative pressure plate.
